(19) United States
(12) Patent Application Publication
(10) Pub. No.: US 2021/0098970 A1
(43) Pub. Date: Apr. 1, 2021

(54) ISOLATOR-FREE LASER

(71) Applicant: II-VI DELAWARE, INC., Wilminton, DE (US)

(72) Inventor: Yasuhiro Matsui, Milpitas, CA (US)

(21) Appl. No.: 17/039,744

(22) Filed: Sep. 30, 2020

Related U.S. Application Data
(60) Provisional application No. 62/908,990, filed on Oct. 1, 2019.

(51) Int. Cl. H01S 5/14; H01S 5/125; H01S 5/12; H01S 3/08

(52) U.S. Cl. CPC H01S 5/141; H01S 3/08059; H01S 5/1203; H01S 5/125

(57) ABSTRACT

An isolator-free laser includes an etalon, an active section, and a low reflection (LR) mirror. The etalon includes a passive section of the isolator-free laser and a reflection profile. The active section is coupled end to end with the passive section. The active section has a distributed feedback (DFB) grating and a lasing mode at a long wavelength side of a reflection peak of the reflection profile. The LR mirror is formed on a front facet of the passive section. The long wavelength edge of the reflection peak of the reflection profile may have a slope greater than 0.006 GHz⁻¹. A RIN of the isolator-free laser under −20 decibels (dB) external cavity optical feedback may be less than or equal to −130 dBc/Hz.

### CROSS-REFERENCE TO RELATED APPLICATION

This application claims the benefit of and priority to U.S. Provisional Patent App. No. 62/908,990 filed Oct. 1, 2019. The 62/908,990 application is incorporated herein by reference.

### FIELD

The embodiments discussed herein are related to an isolator-free laser.

### BACKGROUND

Unless otherwise indicated herein, the materials described herein are not prior art to the claims in the present application and are not admitted to be prior art by inclusion in this section.

The performance of lasers used as optical transmitters in optical communication systems is impaired by reflections at, e.g., the end faces of optical fibers or breaks in the optical fibers. Light may be coupled back into the laser from such an external cavity with a different phase position or a different polarization and may produce parasitic modes in the laser which result in an undesired change of the emitted frequency or in a reduction of the emitted amplitude.

Such external cavity feedback is commonly suppressed by an optical isolator positioned at the output of the laser. Optical isolators allow transmission of light in only one direction. Optical isolators typically include a Faraday rotator and first and second polarizers or first and second birefringent wedges. Optical systems with lasers and optical isolators also typically include at least one lens at the input of the optical isolator to collimate the output of the laser into the optical isolator and at least one lens at the output of the optical isolator to focus the output of the optical isolator into an optical fiber. Optical isolators and lenses add cost and increase a size of optical systems.

The subject matter claimed herein is not limited to implementations that solve any disadvantages or that operate only in environments such as those described above. Rather, this background is only provided to illustrate one example technology area where some implementations described herein may be practiced.

### BRIEF SUMMARY OF SOME EXAMPLE EMBODIMENTS

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

In an example embodiment, an isolator-free laser includes an etalon, an active section, and a low reflection (LR) mirror. The etalon includes a passive section of the isolator-free laser and a reflection profile. The active section is coupled end to end with the passive section. The active section has a distributed feedback (DFB) grating and a lasing mode at a long wavelength edge of a reflection peak of the reflection profile. The LR mirror is formed on a front facet of the passive section. The long wavelength edge of the reflection peak of the reflection profile has a slope greater than 0.006 gigahertz⁻¹ (GHz⁻¹) at the lasing mode. A relative intensity noise (RIN) of the isolator-free laser under −20 decibels (dB) external cavity optical feedback is less than or equal to −130 dBc/Hz.

In another example embodiment, an isolator-free laser includes an etalon, an active section, and a LR mirror. The etalon includes a passive section of the isolator-free laser and a reflection profile with a reflection peak. The active section is coupled end to end with the passive section. The active section has DFB grating and a lasing mode aligned to a long wavelength edge of the reflection peak of the reflection profile. The LR mirror is formed on a front facet of the passive section. Alignment of the lasing mode of the active section to the long wavelength edge of the reflection peak of the reflection profile is configured to suppress change in threshold current of the active section under external cavity optical feedback.

In another example embodiment, an optical system includes an optical fiber and an isolator-free laser optically coupled to the optical fiber. The isolator-free laser includes an etalon or a DBR mirror and an active section. The etalon or the DBR mirror includes a passive section of the isolator-free laser and a reflection profile. The active section is coupled end to end with the passive section. The active section has a lasing mode aligned to a long wavelength edge of a reflection peak of the reflection profile. Alignment of the lasing mode of the active section to the long wavelength edge of the reflection peak of the reflection profile is configured to suppress change in threshold current of the active section under external cavity optical feedback. The optical system is devoid of an optical isolator in an optical path between the optical fiber and the isolator-free laser.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 illustrates an example semiconductor laser, implemented as a distributed reflector (DR) laser;

FIG. 2 illustrates an optical transmission spectrum of a DR laser such as the DR laser of FIG. 1;

FIG. 3 illustrates example modulation spectra of a distributed feedback (DFB) region relative to a DBR transmission profile of a DBR region of the laser of FIG. 1;

FIG. 4 illustrates reflection and phase of the DBR region of the laser of FIG. 1;

FIG. 5 illustrates a DBR reflection profile of a DR laser, such as the laser 100 of FIG. 1

FIG. 6A illustrates an optical spectrum of a DR laser such as the DR laser of FIG. 1;

FIG. 6B shows an example of three different DBR mirror calculations represented by three different DBR reflection profiles;

FIG. 7A illustrates another example semiconductor laser, implemented as a two-kappa DBR laser;

FIG. 7B illustrates another example semiconductor laser, implemented as a DFB laser with weak optical feedback (DFB+R laser);

FIG. 7C illustrates various reflection profiles of another example DFB+R laser;

FIG. 8 illustrates an example modulation spectrum of an active section of a DR laser relative to a DBR reflection profile of a DBR section of the DR laser;

FIG. 9 illustrates a model of a laser cavity;

FIG. 10 illustrates an example isolator-free laser with an active section, a passive section, an HR mirror, a modulation contact, and a bias contact; and

FIG. 11 shows the sigma for noise distribution for DC noise measured by DCA (Agilent DCA-X 86100D) with a 28-GHz BW electrical filter (Plug-in) for each of a DFB laser, a DFB+R laser, a two-kappa DBR laser, and a DR laser,

all arranged in accordance with at least one embodiment described herein.

### DETAILED DESCRIPTION OF SOME EXAMPLE EMBODIMENTS

This application is related to U.S. Pat. No. 10,063,032 issued Aug. 28, 2018 which is incorporated herein by reference.

Embodiments described herein include various directly modulated laser (DML) configurations suitable for isolator-free operation. Such DMLs may be referred to as isolator-free lasers. In general, each of the isolator-free lasers may realize a strong detuned-loading effect by aligning a lasing mode of the laser to a relatively steep filter or mirror edge. Accordingly, modulation of an active section of the laser may modulate cavity loss of the laser and increase intrinsic speed of the laser. Three example isolator-free lasers are described herein, including a distributed reflector (DR) laser, a two-kappa distributed Bragg reflector (DBR) laser, and a distributed feedback (DFB) laser with weak optical feedback (hereinafter DFB+R laser). Each of the DR laser, the two-kappa DBR laser, and the DFB+R laser will be described in turn. The principles described herein may be applied to other laser designs to achieve isolator-free operation.

Reference will now be made to the drawings to describe various aspects of example embodiments of the invention. It is to be understood that the drawings are diagrammatic and schematic representations of such example embodiments, and are not limiting of the present invention, nor are they necessarily drawn to scale.

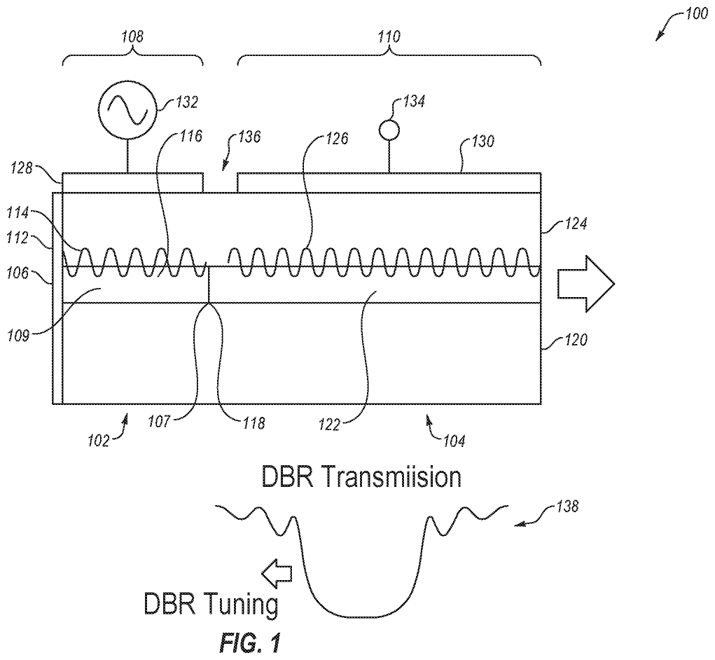

FIG. 1 illustrates an example semiconductor laser 100 (hereinafter “laser 100”), arranged in accordance with at least one embodiment described herein. The laser 100 may be a DR laser and an isolator-free laser. The laser 100 includes a DFB region 102 and a DBR region 104 that together form a laser cavity. The DFB region 102 may have a lasing mode at a long wavelength edge of a peak of a DBR reflection profile of the DBR region 104.

The laser 100 may be configured to be insensitive to optical feedback from an external cavity and thus may be implemented without an optical isolator in optical systems that have historically required an optical isolator, e.g., systems that are intolerant to external cavity optical feedback. In this and other embodiments, the alignment of the lasing mode to the long wavelength edge of the peak of the DBR reflection profile may be configured to suppress change in threshold current of the DFB region 102 under in-phase external cavity optical feedback. For example, a reduction in threshold current and carrier density of the DFB region 102 caused by in phase external cavity optical feedback may be offset and/or canceled by an increase in threshold current of the DFB region 102 that results from reduction of reflectivity of the DBR region 102 caused by the reduction in carrier density. In this and other embodiments, a relative intensity noise (RIN) of the laser 100 under −20 decibels (dB), −10 dB, or even −5 dB or more external cavity optical feedback may be less than or equal to −140 dBc/Hz, less than or equal to −155 dBc/Hz, or even less. Embodiments described herein may alternatively include other lasers, such as two-kappa DBR lasers and DFB+R lasers, that are similarly configured to be insensitive to external cavity optical feedback.

Referring to FIG. 1, the DFB region 102 may extend from a backside 106 to a frontside 107. The DFB region 102 may be included as part of an active section 108 of the laser 100. The DFB region 200 may include a gain section 109 that extends from the backside 106 to the frontside 107. A high reflection (HR) coating or mirror 112 may be disposed and/or formed on the backside 106, in optical communication with the gain section 109.

The gain section 109 of the DFB region 102 may include a DFB grating 114 and a multiple quantum well region (“MQW region”) 116. The DFB grating 114 may have a kappa of about 120 cm⁻¹, or higher or lower than 120 cm⁻¹. Generally, for instance, the DFB grating 114 may have a kappa in a range from 100 to 180 cm⁻¹. The MQW region 116 may include multiple quantum wells. In some embodiments, the quantum wells may be compressively-strained and formed from aluminum gallium indium arsenide (AlGaInAs) or other suitable materials. In these and other embodiments, the DFB region 102 may have a length in a range from 30 micrometers (μm) to 100 μm and the gain section 109 may have a corresponding length. For instance, the DFB region 102 and the gain section 109 may each have a length of 50 μm in some embodiments.

The HR coating 112 may be formed from alternating layers of silicon (Si) and aluminum oxide (e.g., Al₂O₃) or other suitable materials. The HR coating 112 may have a reflectivity of approximately 93%, or higher or lower than 93%.

The DBR region 104 may extend from a backside 118 to a frontside 120 such that the frontside 107 of the DFB region 102 is in optical communication with the backside 118 of the DBR region 104. The DBR region 104 may be included as part of a passive section 110 of the laser 100. The DBR region 104 may include a passive grating section 122 that extends from the frontside 120 toward the backside 118 to optically communicate with the gain section 109 of the DFB region 102. An anti-reflective coating (“AR coating”) 124 may be disposed and/or formed on the frontside 120, in optical communication with the passive grating section 122.

The passive grating section 122 may include a DBR grating 126. The DBR grating 126 may have a kappa of about 180 cm⁻¹, or higher or lower than 180 cm⁻¹. Generally, for instance, the DBR grating 126 may have a kappa in a range from 100 to 200 cm⁻¹. In some embodiments, the passive grating section 122 may be formed from InGaAsP for a bandgap wavelength of 1.1 μm-1.3 μm for lasing operation at 1300 nanometers (nm). In these and other embodiments, the DBR region 104 may range in length from 30 μm to 300 μm and the passive grating section 122 may range in length correspondingly. For instance, the DBR region 104 and the passive grating section 122 may have a length of 200 μm in some embodiments.

The AR coating 124 may be formed from Al₂O₃ and titanium dioxide (TiO₂), such as a double-layer Al₂O₃/TiO₂ AR coating, or other suitable layers and/or materials. The AR coating 124 may have a reflectivity of approximately 1%, or a reflectivity of more or less than 1%.

In an example embodiment, the DFB region 102 may be 50-100 μm in length and the DBR region 104 may be 200 μm in length, or more generally 150-250 μm in length. The DFB region 102 and the DBR region 104 may be integrated by a butt-joint process. The DFB grating 114 may extend to a length of approximately 50-100 μm. As already mentioned, the DFB grating 114 may have a grating strength kappa of approximately 120 cm⁻¹ and the DBR grating 126 may have a grating strength kappa of approximately 180 cm⁻¹. PN blocking layers may be grown for the buried-hetero structure and the parasitic capacitance in the blocking layer may be reduced by forming double channels (e.g., a double channel stripe), and using BCB under the contact pad. The estimated parasitic capacitance may be 0.37 picofarads (pF), providing an RC 3-dB cutoff frequency of 22 gigahertz (GHz) for the measure resistance of 20 ohms. In order to lower the parasitic capacitance, Fe-doped InP may be used for the current blocking region in the laser 100.

Each of the DFB region 102 and the DBR region 104 has a respective contact 128 or 130 through which a modulation signal 132 and/or bias 134 may be provided, as illustrated. A gap 136 is provided between the contact 128 of the DFB region 102 and the contact 130 of the DBR region 104, referred to as a contact gap 136. The contact gap 136 may be about 10 μm between the two contacts 128 and 130, or more or less than 10 μm. In some embodiments, the laser 100 may be implemented as a split-contact DR laser, in which case the contact 130 may be split in two.

FIG. 1 additionally includes an optical transmission spectrum 138 of the DBR region 104 according to at least one embodiment.

As explained in further detail below, DR lasers according to some embodiments described herein may simultaneously exhibit two or more of a photon-photon (p-p) resonance (PPR) effect, a detuned-loading effect, and an in-cavity frequency modulation-to-amplitude modulation (FM-AM) conversion effect. At least one example embodiment of the DR lasers described herein may achieve a 3-dB bandwidth (BW) of 55 GHz and 112 Gb/s PAM-4 modulation. Alternatively or additionally, DBR lasers according to some embodiments described herein may simultaneously exhibit two or more of the PPR effect, the detuned-loading effect, and the in-cavity FM-AM conversion effect.

In more detail, the integrated external cavity formed by a passive waveguide (e.g., in the form of the DBR region 104) enables, during modulation, the excitation of an additional cavity mode located in the vicinity of the main lasing mode, which is the main DFB mode in the case of a DR laser. This causes a resonant enhancement of the modulation sideband that is close to the adjacent cavity mode. The PPR effect can be used to extend the modulation bandwidth beyond the bandwidth of the solitary DFB, which may be determined by the intrinsic resonant frequency (Fr). Some embodiments described herein include semiconductor lasers with photon-photon resonance frequency of 50-100 GHz, 20-80 GHz, or 70 GHz or less.

The detuned-loading effect is also known to enhance the modulation BW of DMLs. This effect has been reported for DBR lasers where the dispersive nature of a Bragg mirror dynamically changes the mirror loss and the penetration depth into the DBR section as the lasing frequency is modulated. When the lasing happens on the long-wavelength flank of the Bragg mirror, the laser chirp is translated into an effective enhancement of the differential gain, and thus improves the speed of the lasers.

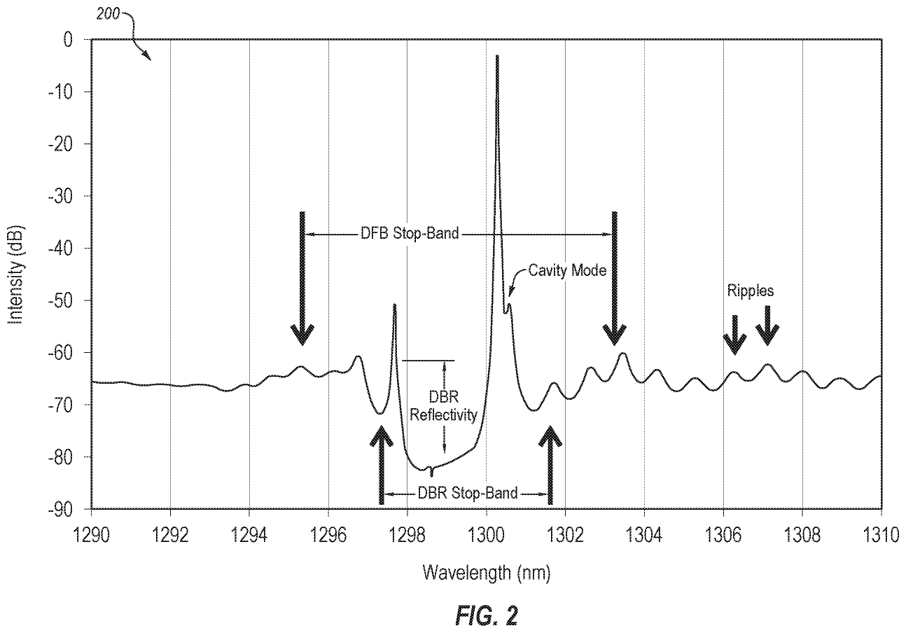

FIG. 2 illustrates an optical transmission spectrum 200 of an example DR laser, arranged in accordance with at least one embodiment described herein. For instance, the laser 100 of FIG. 1 may have the optical transmission spectrum 200 of FIG. 2.

With combined reference to FIGS. 1 and 2, light may exit the laser 100 to the right, passing through the DBR region 104. The DBR region 104 has a reflection profile that is the inverse of the transmission profile 138 of FIG. 1 and thus blocks light within a certain band of frequencies at the center of the profile, referred to as the “DBR stop-band” in FIG. 2. The DBR stop-band width is roughly 5 nm in the optical transmission spectrum 200 of FIG. 2, and may be determined by the length of the DBR region 104 or the DBR grating 126 and/or by the kappa of the DBR grating 126. In the optical transmission spectrum 200, the DBR stop-band for the DBR region 104 is clearly visible in FIG. 2. Also, smaller ripples in the background (some of which are denoted as “Ripples” in FIG. 2) may be determined by the length of the DBR 104 region or the DBR grating 126. The DFB region 102 also has a grating, e.g., the DFB grating 114, and the stop band for the DFB region 102 is labeled “DFB stop-band” in FIG. 2. The DFB stop-band is much wider at roughly 8 nm due to short cavity length (50 μm in this example) and weaker kappa for the DFB region 102 compared to the DBR region 104.

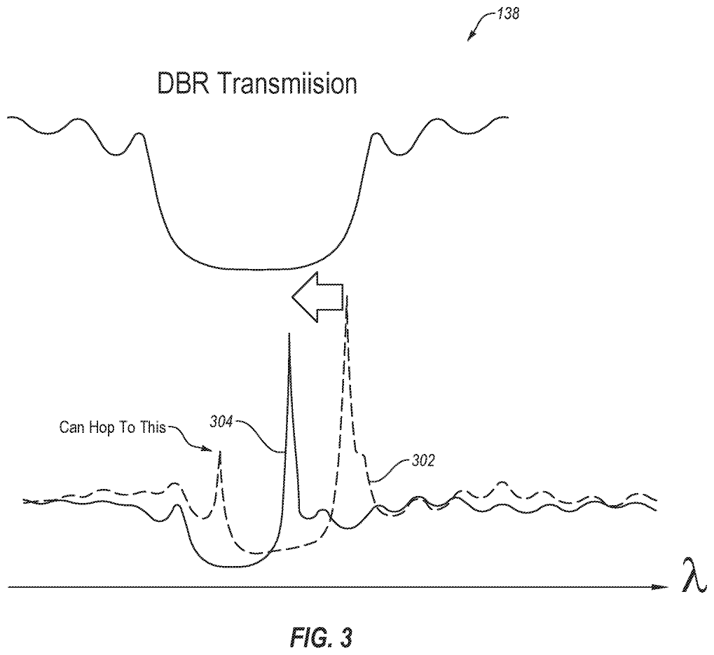

FIG. 3 illustrates example modulation spectra 302, 304 of the DFB region 102 relative to the DBR transmission profile 138 of the DBR region 104 of the laser 100 of FIG. 1, arranged in accordance with at least one embodiment described herein. With reference to FIG. 3, and according to some embodiments, lasing of the DFB region 102 occurs at a frequency (or wavelength) on the right edge of the DBR stop-band. Then, when the laser 100 is modulated (e.g., through modulation of the DFB region 102), lasing frequency changes due to frequency chirp toward shorter wavelength, e.g., from the peak of the spectrum 302 to the peak of the spectrum 304, as the modulation goes from the bias for the 0 bits to the bias for the 1 bits. This shift to shorter wavelength reduces the transmission (or increases the reflection) of the laser cavity. In other words, the loss of the laser cavity is reduced dynamically. This can effectively enhance the differential gain, and increase the intrinsic speed of the laser 100. This effect is called “detuned-loading effect”.

To maximize the detuned-loading effect, a relatively steep slope on the edge of the DBR region 104 may be realized. Also, if the laser cavity length is long, the space between longitudinal modes gets smaller. In this case, as the lasing wavelength is tuned on the edge of the DBR region 104, a mode hop can happen to the left side in FIG. 3 (or more generally toward the short wavelength side) if the laser cavity is relatively long. To avoid mode hop, it may be better to use a short-cavity laser and narrow DBR stop-band for the DBR region 104 as disclosed herein (e.g., as described with respect to FIG. 2).

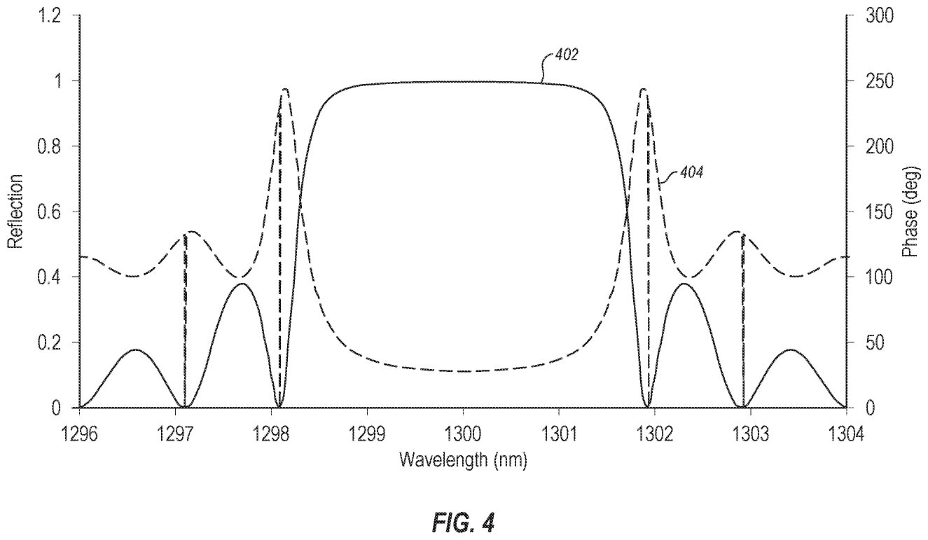

FIG. 4 illustrates reflection 402 and phase 404 of the DBR region 104 of the laser 100 of FIG. 1, each as a function of wavelength, arranged in accordance with at least one embodiment described herein. The rapid change in phase around 1302 nm in the example of FIG. 4 means that the light can penetrate deep into the DBR region 104. So, it is possible to excite an integrated “external cavity mode”.

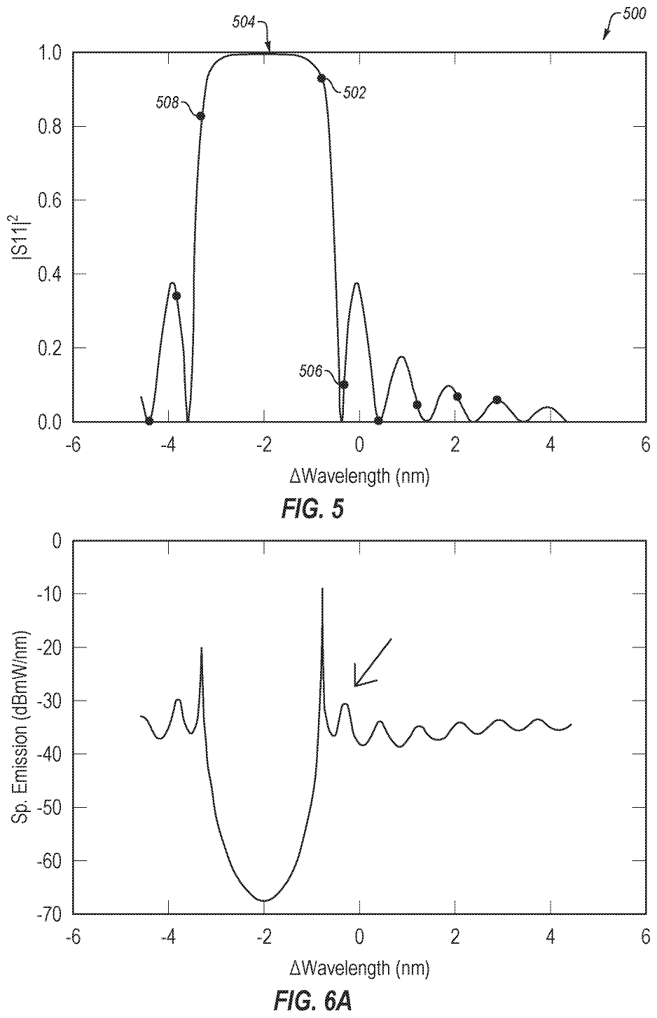

This situation is explained with reference to FIG. 5, which illustrates a DBR reflection profile 500 of a DR laser, such as the laser 100 of FIG. 1, arranged in accordance with at least one embodiment described herein. A small dot labeled “502” in FIG. 5 (hereinafter “lasing mode 502”) just right of a peak 504 of the DBR reflection profile 500 is at the lasing mode wavelength for a DFB region of the DR laser (or alternatively at the lasing mode wavelength of a two-kappa DBR laser or the lasing mode wavelength of a DFB+R laser). And at the bottom of the DBR reflection profile 500, an integrated external cavity mode is designated at 506.

As mentioned, the lasing mode 502 represents the lasing mode wavelength (or main mode) of the DFB region of the DR laser or more generally of an active region of a laser. The DBR reflection profile 500 additionally includes a dot labeled “508” (hereinafter “side mode 508”) just left of the peak 504 at a side mode wavelength of the DFB region. The side mode 508 is another mode on the opposite side of the DBR peak 504 from the lasing mode 502. When the phase condition of lasing changes, for example, by injection of current into the gain section (e.g., gain section 109 of FIG. 1) of the DFB region, local heating happens to the gain section. The local heating changes the index of refraction of the gain section of the DFB region and shifts those mode positions (e.g., the lasing mode 502 and the side mode 508) toward longer wavelengths. As a result, the lasing mode 508 moves down on the increasingly steep longer wavelength slope (or edge) of the peak 504 of the DBR reflection profile 500, thereby experiencing decreased reflectivity/increased transmission from the DBR region. This increases the detuned-loading effect and enhances the speed of the DR laser. However, the side mode 508 moves up on the decreasingly steep shorter wavelength slope of the peak 504 of the DBR reflection profile 500, thereby experiencing increased and higher reflectivity from the DBR region than the lasing mode 502. As a result, the mode of the DFB region can hop from the lasing mode 502 to the side mode 508. Sometimes hysteresis is observed when photon density in the cavity is very high, but the foregoing is roughly true. So, the speed enhancement by detuned-loading effect is limited by the mode hop.

To avoid mode hop behavior, a DBR region with a relatively narrower peak in its DBR reflection profile may be used in the DR laser. Such a DBR region may result from forming the DBR region relatively longer in length with kL>2 where kappa is grating coupling coefficient and L is the length of the DBR region. A relatively shorter length for the DFB region may also help avoid mode hop behavior because the frequency spacing between the lasing mode 502 and the side mode 504 may increase with decreasing length of the DFB region, and can avoid mode hop. Use of a relatively stronger grating in the DFB region may also help to avoid mode hop by increasing the threshold gain difference between the main DFB mode (e.g., the lasing mode 502) and the DFB side mode (e.g., side mode 508).

Phase condition can be tuned also by current injection to the DBR section. In this case, the envelope of the DBR reflection profile may move toward the shorter wavelength.

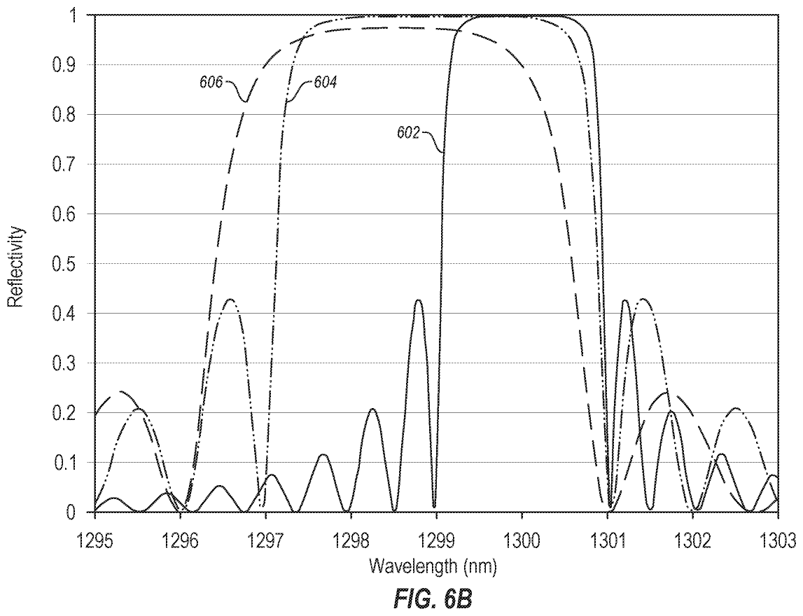

FIG. 6A illustrates a corresponding optical spectrum of a DR laser, such as the laser of FIG. 1. The presence of an integrated external cavity mode can be seen in FIG. 6A and is designated by an arrow.

Some embodiments described herein leverage PPR in combination with detuned-loading to improve performance of the laser. In short, PPR means there is an additional mode, e.g., the integrated external cavity mode 506 of FIG. 5, near the main mode (or the lasing mode 502), and the integrated external cavity mode 506 can beat with the main mode, and help to modulate the light. As illustrated in FIG. 5, the integrated external cavity mode 506 is near the null of Bragg reflection on the long wavelength side. As illustrated in FIG. 4, the phase 404 of the DBR mirror changes rapidly around this null point (dip of reflection). At this wavelength, the wavelength of incident light does not match with the pitch of grating written on the waveguide of the DBR region. So, reflection does not happen efficiently, therefore reflection drops. That means that the light can penetrate deeper to the DBR region before it is eventually reflected. Thus, we can call it an integrated cavity mode or integrated external cavity mode that travels deeper into the DBR region.

Embodiments described herein may locate the integrated external cavity mode 506 close to the main lasing mode (e.g., lasing mode 502) because the beat frequency of these modes can help the modulation response of the laser at around the corresponding frequency. To locate the integrated external cavity mode 506 close to the lasing mode 502, the DBR reflection profile may have a very sharp drop of reflection near the edge. For example, the long wavelength edge of the DFB reflection peak of the DBR reflection profile may have a slope of at least 0.006 GHz⁻¹. Such a sharp drop of reflection near the edge can be realized, again, by using longer DBR length and corresponding kappa to realize kL>2 (corresponding reflection ˜>90%). Such a condition may also satisfy the condition for strong detuned-loading, so it is possible to achieve the two effects simultaneously.

FIG. 6B shows an example of three different DBR mirror calculations represented by DBR reflection profiles 602, 604, and 606, arranged in accordance with at least one embodiment described herein. By comparing the two cases for DBR reflection profile 602: L=400 μm, kappa=100 cm⁻¹ (kL=4), and DBR reflection profile 604: L=200 μm, kappa=200 cm⁻¹ (kL=4), it can be seen that sharper edge can be obtained for longer DBR length when kL is kept constant. Also, it can be seen that the width of stopband becomes narrower for the DBR reflection profile 602 for longer DBR length. By comparing the two cases for DBR reflection profile 604: L=200 μm, kappa=200 cm⁻¹ (kL=4), and DBR reflection profile 606: L=130 μm, kappa=200 cm⁻¹ (kL=2.6), it can be seen that sharper edge can be obtained for longer DBR length when kappa is kept constant. Therefore, it is preferred to use longer DBR length in order to reduce the stop band to avoid mode hop and therefore create a strong detuned-loading effect. At the same time, the frequency difference between the main lasing mode on the edge of the Bragg mirror/DBR reflection profile and the first null point (1301 nm in the example of FIG. 6B) can be minimized to reduce the PPR frequency to enhance the S21 response.

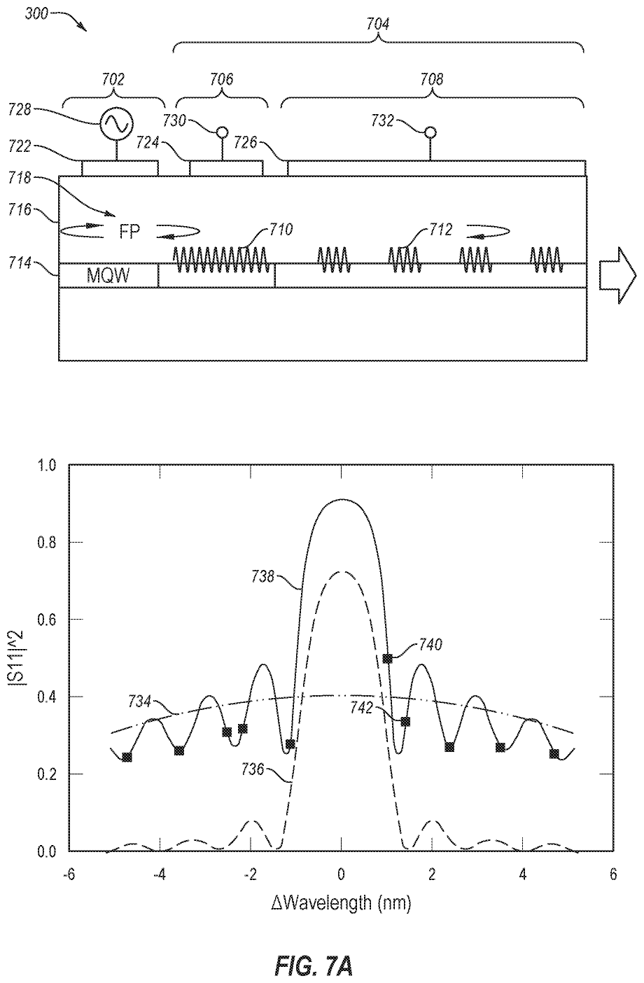

FIG. 7A illustrates another example semiconductor laser 700 (hereinafter “laser 700”), arranged in accordance with at least one embodiment described herein. The laser 700 may be a two-kappa DBR laser and an isolator-free laser. The laser 700 includes an active section 702 and a passive section 704 that together form a laser cavity. The active section 702 may have a lasing mode at a long wavelength side of a peak of a DBR reflection profile of the passive section 704. A temperature and/or bias current, both of which may be actively controlled, may determine the lasing mode of the active section 702.

The passive section 704 may include a first DBR section 706 and a second DBR section 708. The first DBR section 706 may have a first DBR grating 710 with a first kappa. The first DBR section 706 may be relatively short, such as 15 micrometers in length. The first kappa of the first DBR grating 710 may be relatively strong, such as 500 cm⁻¹.

The second DBR section 708 may have a second DBR grating 712 with a second kappa. The second DBR section 706 may be relatively long, such as 150 micrometers. The second kappa of the second DBR grating 712 may be less than the first kappa of the first DBR grating 710. As illustrated in FIG. 7A, the second DBR grating 712 includes a sampled grating with an effective kappa of 80 cm⁻¹. In general, the kappa of a DBR grating as used herein may refer to the effective kappa of the DBR grating which may be the same as the actual kappa in the case of a uniform grating.

The active section 702 may include a multiple quantum well (MQW) gain layer 714 or other suitable gain layer and may have a lasing mode. In the example of FIG. 7A, the active section 702 may have a length of 50 micrometers.

An HR mirror 716, also referred to as a rear mirror, is formed on a rear facet of the active section 702. The HR mirror 716, the active section 702, and the first DBR section 706 may form a Fabry-Perot (FP) cavity 718, which may increase a longitudinal confinement factor of the two-kappa DBR laser 700 compared to uniform (e.g., single kappa) DBR lasers. Addition of the second DBR section 708 at the output of the FP cavity 718 creates the detuned-loading effect in the two-kappa DBR laser 700. Accordingly, modulation of the active section 702 may modulate cavity loss and increase intrinsic speed of the two-kappa DBR laser 700.

As illustrated in FIG. 7A, the two-kappa DBR laser 700 may additionally include modulation contact 722 and first and second bias contacts 724, 726 electrically coupled to, respectively, the active section 702, the first DBR section 706, and the second DBR section 708. A modulation signal 728 may be provided through the modulation contact 722 to the active section 702. A first bias signal 730 may be provided through the first bias contact 724 to the first DBR section 706. A second bias signal 732 may be provided through the second bias contact 726 to the second DBR section 708. Alternatively or additionally, current tuning may be applied to one or both of the first and second DBR sections 706, 708 through the corresponding first and second bias contacts 724, 726 to tune PPR frequency of the two-kappa DBR laser 700.

In some embodiments, the two-kappa DBR laser 700 may further include a low reflection (LR) mirror formed at the output facet of the second DBR section 708 to improve side-mode suppression ratio (SMSR). The LR mirror may have a reflectivity of, e.g., 1% or less.

FIG. 7A additionally illustrates a reflection profile 734 of the first DBR section 706 (hereinafter first DBR reflection profile 734), a reflection profile 736 of the second DBR section 708 (hereinafter second DBR reflection profile 736), and a reflection profile 738 of the two-kappa DBR laser 700 as a whole (hereinafter two-kappa DBR laser reflection profile 738). As illustrated by the first DBR reflection profile 734, the first DBR section 706 has a broad DBR reflection peak with a relatively low maximum reflection. As illustrated by the second DBR reflection profile 736, the second DBR section 708 has a much narrower DBR reflection peak with relatively steep long wavelength edge. The two-kappa DBR laser reflection profile 738 is the aggregate reflection profile of the two-kappa DBR laser 700 from the combination of the first and second DBR reflection profiles 734, 736. As illustrated, the long wavelength edge of the two-kappa DBR laser reflection profile 738 is even steeper at the lasing mode 740 of the active section 702 than the long wavelength edge of the second DBR reflection profile 736. The long wavelength edge of the DBR reflection peak of the two-kappa DBR laser reflection profile 738 may have a slope of at least 0.006 GHz⁻¹ at a lasing mode 740 of the two-kappa DBR laser 700.

FIG. 7A further illustrates a PPR mode 742 of the two-kappa DBR laser 700. The PPR mode 742 may have a PPR frequency in a range of 20 GHz to 80 GHz. Alternatively or additionally, the PPR frequency may be tuned over a range by detuning the first and second DBR sections 706, 708 relative to each other with current tuning. The tuning range of the PPR frequency may be 20 GHz to 80 GHz.

The laser 700 may be configured to be insensitive to optical feedback from an external cavity and thus may be implemented without an optical isolator in optical systems that have historically required an optical isolator. As described above, the alignment of the lasing mode to the long wavelength edge of the DBR reflection peak of the two-kappa DBR laser reflection profile 738 may be configured to suppress change in threshold current of the active section 702 under in-phase external cavity optical feedback. For example, a reduction in threshold current and carrier density of the active section 702 caused by in phase external cavity optical feedback may be offset and/or canceled by an increase in threshold current of the active section 702 that results from reduction of reflectivity of the passive section 704 caused by the reduction in carrier density. In this and other embodiments, a relative intensity noise (RIN) of the laser 700 under −20 decibels (dB), −10 dB, or even −5 dB or more external cavity optical feedback may be less than or equal to −140 dBc/Hz, less than or equal to −155 dBc/Hz, or even less.

Additional example aspects of two-kappa DBR lasers are provided in U.S. application Ser. No. 16/691,553 filed Nov. 21, 2019, which is incorporated herein by reference.

FIG. 7B illustrates another example semiconductor laser 750 (hereinafter “laser 750”), arranged in accordance with at least one embodiment described herein. The laser 750 may be a DFB+R laser and an isolator-free laser. As illustrated, the laser 750 includes a passive section 752 and a DFB section 754 (also referred to as an active section). The passive section 752 may have a length of about 120 micrometers. The DFB section 754 may have a length of about 100 micrometers.

The DFB section 754 may include a DFB grating 756 formed in, on, and/or above a MQW gain layer 758 or other suitable gain layer. The DFB grating 756 may include first and second grating portions with a phase shift in between.

An HR mirror 760 is formed on a rear facet of the DFB section 754. A LR mirror 762 is formed on a front facet of the passive section 752. The LR mirror 762 may have a low reflectivity such as 7% or less. An etalon 764 is formed between a portion of the DFB grating 756 at the front of the DFB section 754 and the LR mirror 762. The laser 750 forms a complex-cavity design consisting of a DFB laser itself, e.g., the DFB section 754, and the etalon 764. The etalon 764 is configured to modify cavity loss dynamically due to frequency chirp as the DFB section 754 is modulated. The laser 750 may be referred to as a DFB+R (e.g., DFB plus (weak) reflector) laser 750. Although the LR mirror 762 is described as having a low reflectivity of 7% or less, more generally the etalon 764 may have a low effective reflectivity of 7% or less at its front facet.

FIG. 7B additionally illustrates a reflection profile 766 of the DFB grating 756 (hereinafter DFB reflection profile 766), and a reflection profile 768 of the combined DFB grating 756 and the LR mirror 762 (with a reflectivity of 3%) (hereinafter combined DFB+R reflection cn profile 768) when seen from the DFB section 754 toward the output of the laser 750. As illustrated by the DFB+R reflection profile 768 in FIG. 7B, the etalon 764 formed by the DFB grating 756 and the LR mirror 762 produces strong ripples and hence a strong detuned-loading effect.

FIG. 7C illustrates various reflection profiles 770, 772, 774 of another example DFB+R laser, arranged in accordance with at least one embodiment described herein. The DFB+R laser may be the same as or similar to the DFB+R laser 750 of FIG. 7B where a LR mirror of the DFB+R laser of FIG. 7C has a reflectivity of 4%.

The reflection profile 770 is a reflection profile of a DFB grating of the DFB+R laser (hereinafter DFB reflection profile 770). The reflection profile 772 is a reflection profile of the combined DFB grating and the LR mirror (with a reflectivity of 4%) at low bias (hereinafter combined low bias DFB+R reflection profile 772) when seen from the DFB section toward the output of the DFB+R laser. The reflection profile 774 is a reflection profile of the combined DFB grating and the LR mirror (with a reflectivity of 4%) at high bias (hereinafter combined high bias DFB+R reflection profile 774) when seen from the DFB section toward the output of the DFB+R laser. There is a shift from the combined low bias DFB+R reflection profile 772 to the combined high bias DFB+R reflection profile 772 when the bias increases due to gain compression of the DFB+R laser. This shift is smaller than the frequency chirp that occurs under modulation since the index of the passive section does not change dynamically.

As illustrated in FIG. 7C, each of the combined DFB+R reflection profiles 772, 774 has periodic reflection peaks (or ripples) and valleys and a main lasing mode 776 of the DFB section is aligned to a long wavelength edge of one of the periodic peaks. The edge of the peak to which the main lasing mode 776 is aligned may be relatively steep. For instance, the edge of the peak may have a slope of at least 0.006 GHz⁻¹ at the main lasing mode 776. When the DFB+R laser is intensity modulated from intensity corresponding to 1 bits to intensity corresponding to 0 bits, frequency chirp shifts the main lasing mode 776 to shorter wavelength, e.g., to chirped lasing mode 778. The frequency chirp increases the reflectivity of the etalon of the DFB+R laser, and therefore dynamically reduces the loss of cavity. This is an effective increase in the differential gain, and therefore the speed of laser is improved according to the detuned-loading effect. Thus, in some embodiments, modulation of the DFB section of a DFB+R laser as described herein modulates cavity loss of the DFB+R laser and increases intrinsic speed of the DFB+R laser.

The laser 750 of FIG. 7B and/or the DFB+R laser of FIG. 7C may be configured to be insensitive to optical feedback from an external cavity and thus may be implemented without an optical isolator in optical systems that have historically required an optical isolator. Alignment of the lasing mode to the long wavelength edge of one of the periodic peaks of the combined DFB+R reflection profile 768, 772, 774 may be configured to suppress change in threshold current of the DFB section 754 under in-phase external cavity optical feedback. For example, a reduction in threshold current and carrier density of the DFB section 754 caused by in phase external cavity optical feedback may be offset and/or canceled by an increase in threshold current of the DFB section 754 that results from reduction of reflectivity of the etalon 764 caused by the reduction in carrier density. In this and other embodiments, a relative intensity noise (RIN) of the laser 750 of FIG. 7B and/or the DFB+R laser of FIG. 7C under −20 decibels (dB), −10 dB, or even −5 dB or more external cavity optical feedback may be less than or equal to −140 dBc/Hz, less than or equal to −155 dBc/Hz, or even less.

Additional example aspects of DFB+R lasers are provided in U.S. application Ser. No. 16/691,549 filed Nov. 21, 2019, which is incorporated herein by reference.

Embodiments described herein may alternatively or additionally include DR+R (e.g., DR plus (weak) reflector) lasers. The DR+R laser may combine aspects of, e.g., the DR laser 100 of FIG. 1 and the DFB+R laser of FIG. 7B. For example, the DR+R laser may include an active DFB section (such as the active section 108 of FIG. 1 or the DFB section 754 of FIG. 7B) sandwiched between a passive DBR section (such as the passive section 110 of FIG. 1) and a passive etalon section (such as the passive section 752 with weak reflectivity of FIG. 7B).

The modulation spectra of semiconductor lasers have ripples due to the periodic nature of the laser cavities in such lasers. When the phase of reflected light at a given wavelength matches the phase prior to reflection, constructive interference occurs, resulting in a corresponding ripple or peak at the given wavelength in the modulation spectrum. When the phase of the reflected light at a given wavelength does not match, destructive interference occurs, resulting in a corresponding valley at the given wavelength in the modulation spectrum. Inclusion of a DFB grating in the active section (e.g., as in DR lasers and DFB+R lasers) emphasizes one of the ripples, resulting in a main lasing mode. The period from peak to peak is proportional to the reflection cavity length; the shorter the cavity, the greater the spacing between ripples and the greater the separation of the ripples from the main lasing mode.

In some optical systems, semiconductor lasers emit optical signals into optical fibers. Some light may be reflected at the input of the optical fiber back toward the laser. Alternatively or additionally, some light may be reflected back toward the laser from cracks or breaks in the optical fiber. Each reflection surface external to the laser itself defines an external cavity. Light reflected back toward the laser from an external cavity may be referred to as external cavity optical feedback. Such external cavity optical feedback is distinguishable from the integrated external cavity mode associated with the PPR effect in that such external cavity optical feedback is reflected back toward the laser from a location that is completely external to the laser, whereas the integrated external cavity mode associated with the PPR effect is reflected from a location within the laser itself, e.g., from a deep penetration location within the DBR region in the case of a DR laser.

The external cavity optical feedback creates ripples in the modulation spectrum of the laser as a function of wavelength, similar to the ripples caused by reflection within the cavity itself. The external cavity optical feedback ripples may be smaller in amplitude than the in cavity ripples, but may be spaced much closer together and to the main lasing mode since the period from peak to peak is proportional to the cavity length and the cavity length of the external cavity optical feedback is much larger than the laser cavity length.

In an ideal laser, the modulation spectrum is completely stable and there is no noise in the optical signals emitted by the laser. Fundamentally, however, lasers exhibit fractuation, e.g., instability in the modulation spectrum arising from quantum mechanics. The amount of fractuation is referred to as the linewidth of the laser. When a neighboring external cavity mode, or ripple, from the external cavity optical feedback is sufficiently close to the main lasing mode, the fractuation couples into the external cavity mode and excites the external cavity mode. The coupling and hopping to the external cavity mode is random as noise, decreasing the signal to noise ratio (SNR) in the output of the laser when directly modulated.

The amount of fractuation in the modulation spectrum of the laser is referred to as the linewidth of the laser or the spectrum linewidth. For coherent applications and/or other applications, lasers with narrow linewidth are preferred. Linewidth is related to the alpha (a) parameter, also referred to as the linewidth enhancement factor. The smaller the alpha parameter, the smaller the linewidth. If the alpha parameter is taken to zero, the resulting linewidth will be very small. When the linewidth is small enough, the nearest external cavity mode may be sufficiently separated from the main lasing mode that the fractuation of the main lasing mode will not couple into the external cavity mode. Lasers that do not couple into and excite the external cavity mode under external cavity optical feedback may therefore be implemented in optical systems without an optical isolator.

It is difficult to take the alpha parameter to zero. For example, lasers with alpha parameter at or near zero have been hypothesized for quantum dot material as the active material of the lasers. A quantum dot is a small dot of material, about the size of the electron wave function, surrounded by a confinement material that provides 3D confinement. However, quantum dot-based lasers do not appear to be suitable for high-speed operation (e.g., 40-50 gigabits/sec (G) or higher) and have thus been limited to not more than about 20 G.

In comparison, lasers described herein include quantum wells and are suitable for high-speed operation. A quantum well is a buried sheet of material with only 1D confinement. Even so, embodiments of lasers described herein may have a sufficiently small alpha parameter to be implemented in optical systems without an optical isolator, e.g., as an isolator-free laser. Example isolator-free lasers described herein have an alpha parameter of 1.2 or lower, or even 1.0 or lower. For example, such isolator-free lasers may have an alpha parameter of about 0.6.

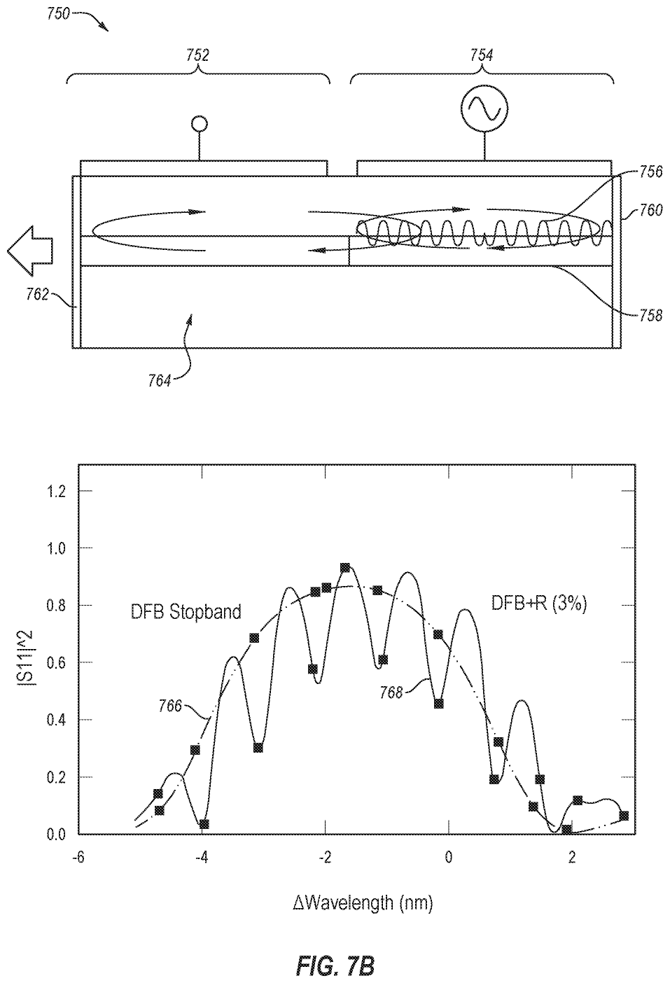

As already described herein, some embodiments leverage the detuned-loading effect, e.g., by aligning the main lasing mode of the laser to the long wavelength edge of a reflection profile (e.g., a DBR reflection profile or etalon reflection profile) of the laser. The behavior of a laser that leverages the detuned-loading effect according to at least one embodiment will now be described with respect to FIG. 8.

FIG. 8 illustrates an example modulation spectrum 802 of an active section of a DR laser, such as the active section 108 of FIG. 1, relative to a DBR reflection profile 804 of a DBR section of the DR laser, arranged in accordance with at least one embodiment described herein. Analogous operating principles apply to two-kappa DBR lasers and DFB+R lasers. As illustrated, a main lasing mode 806 of the modulation spectrum 802 is aligned to a long wavelength edge 808 of the DBR reflection profile 804. Accordingly, lasing of the active section occurs at a frequency (or wavelength) on the right edge of the DBR stop-band.

When the laser is modulated (e.g., through modulation of the active section), lasing frequency changes due to frequency chirp toward shorter wavelength as the modulation goes from the bias for the 0 bits to the bias for the 1 bits and toward longer wavelength as the modulation goes from the bias for the 1 bits to the 0 bits. The frequency/wavelength of the main lasing mode 806 for each of the 1 and 0 bits is designated in FIG. 8 by a corresponding vertical dashed line labeled with, respectively, a 1 or a 0.

The frequency chirp caused by modulation results in a change in reflection as the main lasing mode 806 moves up and down the long wavelength edge of the reflection profile 804. In particular, when the modulation goes from the bias for the 0 bits to the 1 bits, the wavelength of the main lasing mode 806 shifts toward shorter wavelength resulting in increased reflection and thus lower loss. When the modulation goes from the bias for the 1 bits to the 0 bits, the wavelength of the main lasing mode 806 shifts toward longer wavelength resulting in decreased reflection and thus higher loss. The reflectivity of the DBR region of the laser at the wavelengths corresponding to each of the 1 and 0 bits is designated in FIG. 8 by a corresponding horizontal dashed line labeled with, respectively, a 1 or a 0.

The speed or resonant frequency Fr of the laser is proportional to the square root of the differential gain dg/dN, where the differential gain dg/dN is the gain change dg with carrier density change dN. Modulation of the active section causes carrier density change dN, which in turn causes gain change dg. The carrier density change dN from modulation also causes index change dn in the laser through the plasma effect. The index change dn causes the frequency chirp, which in turn causes the reflectivity change of the DBR section when the main lasing mode 806 is aligned to the long wavelength edge 808 of the DBR reflection profile 804. The carrier density N increases as the reflectivity increases, where the increase in reflectivity is effectively a decrease in loss. Thus, the differential gain dg/dN effectively increases as the carrier density N increases, which increases the speed of the laser since the speed of the laser is proportional to the square root of the differential gain dg/dN.

A reduction of the linewidth enhancement factor was discussed in the context of detuned-loading effect in 1988 in Klaus Petermann, “Laser Diode Modulation and Noise,” Kluwer Academic Publishers, ISBN0-7923-1204-X (1988), which is incorporated herein by reference. The detuned-loading effect can effectively enhance the differential gain, and therefore it can reduce the effective linewidth enhancement factor (a.k.a. structure alpha):

$${α}_{eff} = α \frac{{τ}_{L} + \frac{d {φ}_{r}}{d ω} - \frac{1}{α \vert {r}_{m} \vert} \frac{d \vert {r}_{m} \vert}{d ω}}{{τ}_{L} + \frac{d {φ}_{r}}{d ω} + \frac{α}{\vert {r}_{m} \vert} \frac{d \vert {r}_{m} \vert}{d ω}} , \qquad ( 1 )$$

where τ_{L} is the cavity roundtrip time, α is the linewidth enhancement factor as a material parameter without detuned-loading effect, and rₘ and φᵣ are the reflectivity and phase of the DBR mirror, respectively, at the position of the lasing mode.

The reduction of the effective alpha parameter can increase the reflection tolerance of lasers according to formula 2:

$${f}_{ext , c} = \frac{{τ}_{L}^{2}}{4 {( 1 - R )}^{2} / R} ( K {f}_{r}^{2} + {γ}_{0} ) [ \frac{1 + {α}_{eff}^{2}}{{α}_{eff}^{4}} ] , \qquad ( 2 )$$

where R is the facet reflectivity facing to the reflection plane, K is the K-factor, and γ₀ is the damping factor offset. See Jochen Helms et. al., “A simple analytic expression for the stable operation range of laser diodes with optical feedback,” IEEE J. Quantum Electron., 26, 833-836 (1990), which is incorporated herein by reference. This shows that the reduction of the effective alpha parameter can increase the reflection tolerance.

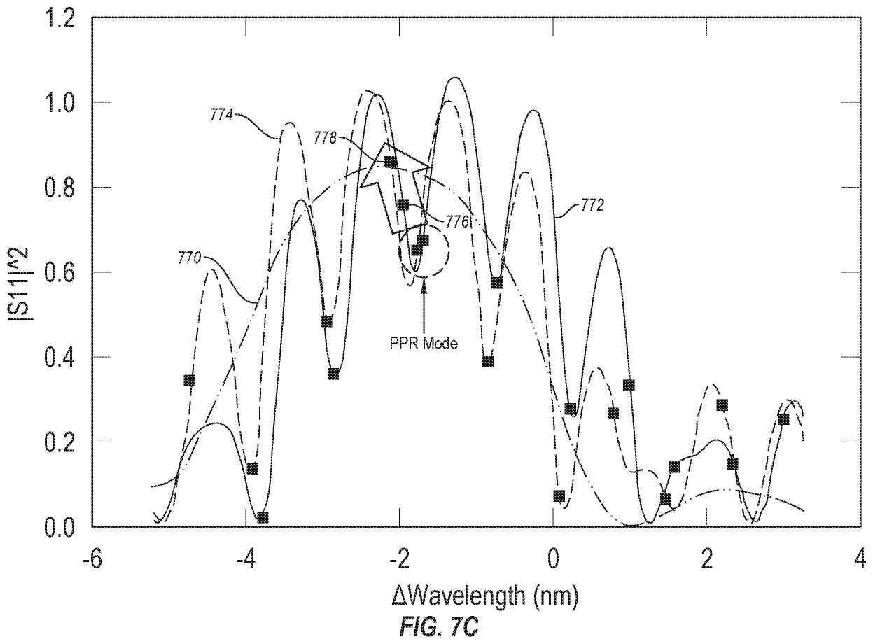

FIG. 9 illustrates a model of a laser cavity, arranged in accordance with at least one embodiment described herein. Current injected into the laser cavity creates spontaneous seed light which experiences gain (amplification) traveling left-to-right and right-to-left in the laser cavity. A reflector at one or both ends reflects at least some of the light, which passes back through the laser cavity in the opposite direction. As illustrated, each end of the laser cavity has a 30% reflector such that about 30% of the light that reaches the reflector is reflected back into the laser cavity and the remaining 70% exits the laser cavity as loss. Light that exits the laser cavity has a phase φ. With sufficient current injection, e.g., at a lasing threshold current Iₜₕ (hereinafter “threshold current Iₜₕ”), lasing occurs in the laser cavity. In particular, lasing occurs when the gain equals the loss.

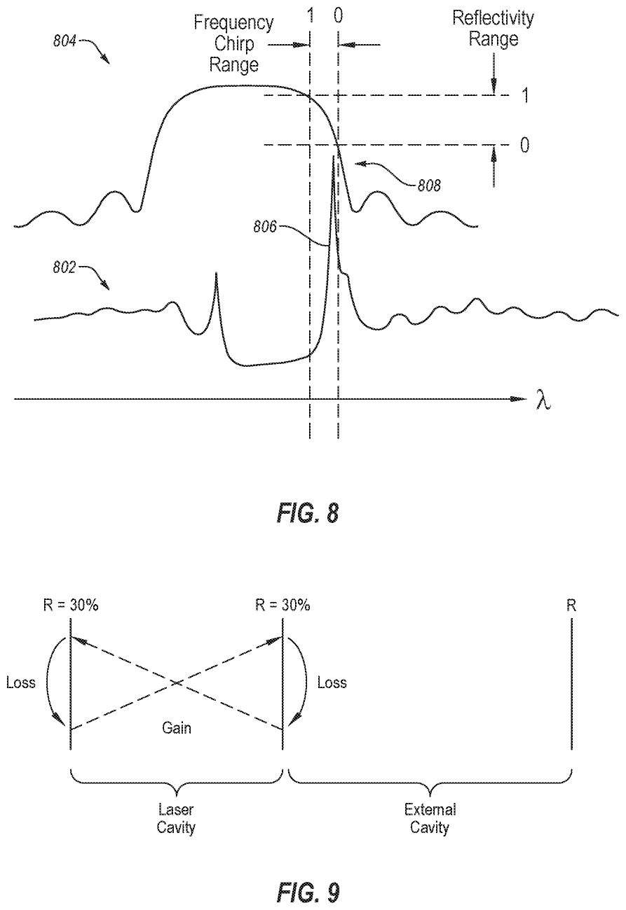

Some of the light that exits the laser cavity is reflected by the external cavity back into the laser cavity, e.g., as external cavity optical feedback. External cavity optical feedback that is out of phase with the light in the laser cavity is ignored by the laser cavity. External cavity optical feedback that is in phase with the light in the laser cavity increases the amount of seed light in the laser cavity which decreases the threshold current Iₜₕ of the laser cavity. The reduction in threshold current Iₜₕ reduces the carrier density N. The reduction in carrier density N shifts the main lasing mode to longer wavelength. When the main lasing mode is shifted to longer wavelength, the mirror reflectivity of the DBR mirror decreases (see FIG. 8) due to the detuned-loading effect. When the mirror reflectivity decreases, the threshold current Iₜₕ increases. The increase in the threshold current Iₜₕ cancels or at least partially cancels the decrease in the threshold current Iₜₕ from the external cavity optical feedback. The foregoing feedback loop is illustrated in more detail in FIG. 10.

FIG. 10 illustrates an example isolator-free laser 1000 (hereinafter laser 1000) with active section 1002, passive section 1004, HR mirror 1006, modulation contact 1008, and bias contact 1010, arranged in accordance with at least one embodiment described herein. The laser 1000 of FIG. 10 is illustrated in a simplified form and may more generally include or correspond to any of the isolator-free lasers described herein, such as the DR laser of FIG. 1, the two-kappa DBR laser of FIG. 7A, or the DFB+R lasers of FIGS. 7B and 7C. FIG. 10 further illustrates a main lasing mode 1012 of the laser 100 and a reflection profile 1014 of the laser 1000, the reflection profile 1014 having a reflection peak 1016, The main lasing mode 1012 is shown in FIG. 10 at two different locations relative to the reflection profile 1014 that may include or be within the boundaries of the “Frequency Chirp Range” denoted in FIG. 8.

The feedback loop may operate as follows. First, under external cavity optical feedback, the threshold current Iₜₕ and thus threshold carrier density Nₜₕ may be reduced. The threshold carrier density Nₜₕ may include the carrier density N associated with the threshold current Iₜₕ. Second, the reduction in threshold carrier density Nₜₕ shifts the main lasing mode 1012 to longer wavelength. Third, when the main lasing mode 1012 is shifted to longer wavelength, the mirror reflectivity R of the DBR mirror is reduced due to the detuned-loading effect. Fourth, when the mirror reflectivity is reduced, the threshold current Iₜₕ and thus the threshold carrier density Nₜₕ increases. The increase in the threshold current Iₜₕ and the threshold carrier density Nₜₕ cancels or at least partially cancels the decrease in the threshold current Iₜₕ and the threshold carrier density Nₜₕ from the external cavity optical feedback. A similar feedback loop may occur in the other isolator-free lasers described herein, such as in the laser 100 of FIG. 1, the laser 700 of FIG. 7A, and the laser 750 of FIG. 7B.

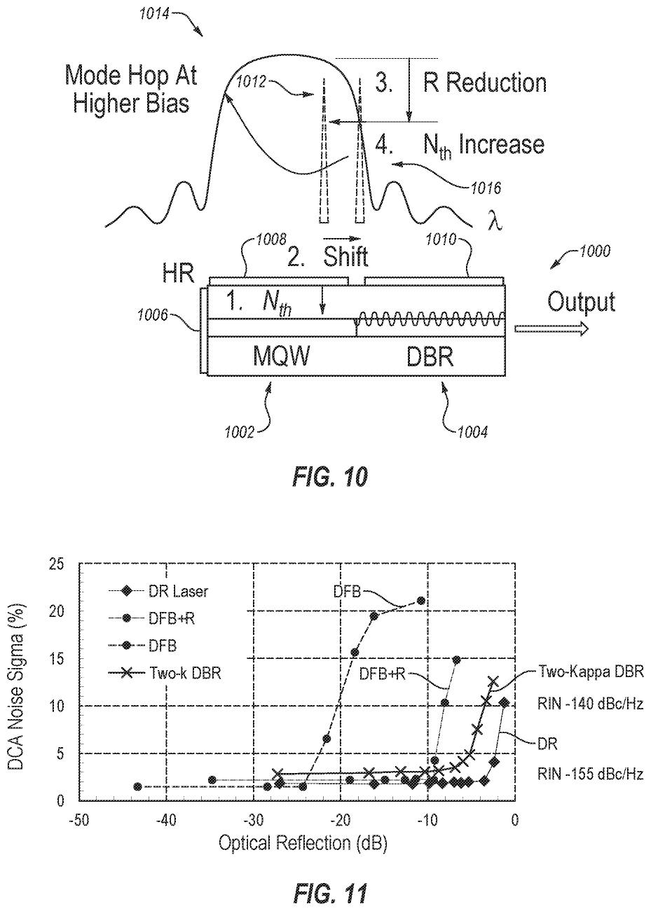

FIG. 11 shows the sigma for noise distribution for DC noise measured by DCA (Agilent DCA-X 86100D) with a 28-GHz BW electrical filter (Plug-in) for each of a DFB laser, a DFB+R laser, a two-kappa DBR laser, and a DR laser, arranged in accordance with at least one embodiment described herein. For the DR laser, the two-kappa DBR laser, and the DFB+R laser, the operation condition was tuned to maximize the modulation BW in order to realize a strong detuned-loading effect. As a result, low noise behavior of −155 dBc/Hz in RIN at 4 GHz, or 2.1% in the sigma of Gaussian noise distribution with respect to the DC average power is maintained up to about −9 dB, −7 dB, and −4 dB for the DFB+R laser, the two-kappa DBR laser, and the DR laser, respectively. The poorer reflection tolerance for DFB+R laser is considered to be due to the higher longitudinal confinement factor for DFB+R laser compared to the two-kappa DBR laser and the DR laser, while still being significantly better than the noise tolerance of the standard DFB laser. The noise sigma of 10% roughly corresponds to −140 dBc/Hz in RIN at 4 GHz. As shown, high-speed operation and isolator-free operation can be simultaneously realized.

Unless specific arrangements described herein are mutually exclusive with one another, the various implementations described herein can be combined in whole or in part to enhance system functionality or to produce complementary functions. Likewise, aspects of the implementations may be implemented in standalone arrangements. Thus, the above description has been given by way of example only and modification in detail may be made within the scope of the present invention.

With respect to the use of substantially any plural or singular terms herein, those having skill in the art can translate from the plural to the singular or from the singular to the plural as is appropriate to the context or application. The various singular/plural permutations may be expressly set forth herein for sake of clarity. A reference to an element in the singular is not intended to mean “one and only one” unless specifically stated, but rather “one or more.” Moreover, nothing disclosed herein is intended to be dedicated to the public regardless of whether such disclosure is explicitly recited in the above description.

In general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). Furthermore, in those instances where a convention analogous to “at least one of A, B, and C, etc.” is used, in general, such a construction is intended in the sense one having skill in the art would understand the convention (e.g., “a system having at least one of A, B, and C” would include but not be limited to systems that include A alone, B alone, C alone, A and B together, A and C together, B and C together, or A, B, and C together, etc.). Also, a phrase presenting two or more alternative terms, whether in the description, claims, or drawings, should be understood to include one of the terms, either of the terms, or both terms. For example, the phrase “A or B” will be understood to include the possibilities of “A” or “B” or “A and B.”

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An isolator-free laser, comprising:
an etalon, the etalon comprising a passive section of the isolator-free laser and a reflection profile;
an active section coupled end to end with the passive section, the active section having a distributed feedback (DFB) grating and a lasing mode at a long wavelength edge of a reflection peak of the reflection profile, the long wavelength edge of the reflection peak of the reflection profile having a slope greater than 0.006 gigahertz⁻¹ (GHz⁻¹) at the lasing mode; and
a low reflection (LR) mirror formed on a front facet of the passive section;
wherein a relative intensity noise (RIN) of the isolator-free laser under −20 decibels (dB) external cavity optical feedback is less than or equal to −130 dBc/Hz.

2. The isolator-free laser of claim 1, wherein the RIN of the isolator-free laser under −10 dB external cavity optical feedback is less than or equal to −130 dBc/Hz.

3. The isolator-free laser of claim 1, wherein the RIN of the isolator-free laser under −5 dB external cavity optical feedback is less than or equal to −130 dBc/Hz.

4. The isolator-free laser of claim 1, wherein the RIN of the isolator-free laser under −20 dB external cavity optical feedback is less than or equal to −155 dBc/Hz.

5. The isolator-free laser of claim 1, further comprising a photon-photon resonance frequency less than or equal to 70 gigahertz.

6. The isolator-free laser of claim 1, wherein the isolator-free laser has an alpha parameter of 1.2 or less.

7. The isolator-free laser of claim 1, wherein the active section has a length of 50 micrometers or less.

8. The isolator-free laser of claim 1, wherein a front portion of the DFB grating, the passive section, and the LR mirror form the etalon.

9. The isolator-free laser of claim 1, further comprising a high reflection (HR) coating formed on a rear facet of the active section.

10. The isolator-free laser of claim 1, wherein a reduction in lasing threshold current and threshold carrier density of the active section that results from external cavity optical feedback is offset by an increase in threshold current of the active section that results from reduction of reflectivity of the etalon or DBR mirror caused by the reduction in threshold carrier density.

11. An isolator-free laser, comprising:
an etalon, the etalon comprising a passive section of the isolator-free laser and a reflection profile with a reflection peak;
an active section coupled end to end with the passive section, the active section having a distributed feedback (DFB) grating and a lasing mode aligned to a long wavelength edge of the reflection peak of the reflection profile; and
a low reflection (LR) mirror formed on a front facet of the passive section;
wherein alignment of the lasing mode of the active section to the long wavelength edge of the reflection peak of the reflection profile is configured to suppress change in threshold current of the active section under external cavity optical feedback.

12. The isolator-free laser of claim 11, wherein the isolator-free laser has an alpha parameter of 1.2 or less.

13. The isolator-free laser of claim 11, wherein the isolator-free laser has an alpha parameter of 1.0 or less.

14. The isolator-free laser of claim 11, wherein a relative intensity noise (RIN) of the isolator-free laser under −15 decibels (dB) external cavity optical feedback is less than or equal to −130 dBc/Hz.

15. The isolator-free laser of claim 11, wherein a relative intensity noise (RIN) of the isolator-free laser under −10 decibels (dB) external cavity optical feedback is less than or equal to −130 dBc/Hz.

16. An optical system comprising:
an optical fiber; and
an isolator-free laser optically coupled to the optical fiber, the isolator-free laser comprising:
an etalon or a distributed Bragg reflector (DBR) mirror, the etalon or the DBR mirror comprising a passive section of the isolator-free laser and a reflection profile; and
an active section coupled end to end with the passive section, the active section having a lasing mode aligned to a long wavelength edge of a reflection peak of the reflection profile;
wherein alignment of the lasing mode of the active section to the long wavelength edge of the reflection peak of the reflection profile is configured to suppress change in threshold current of the active section under external cavity optical feedback; and
wherein the optical system is devoid of an optical isolator in an optical path between the optical fiber and the isolator-free laser.

17. The optical system of claim 16, wherein a reduction in lasing threshold current and threshold carrier density of the active section that results from external cavity optical feedback is offset by an increase in threshold current of the active section that results from reduction of reflectivity of the etalon or DBR mirror caused by the reduction in threshold carrier density.

18. The optical system of claim 16, wherein a relative intensity noise (RIN) of the isolator-free laser under −10 decibels (dB) external cavity optical feedback is less than or equal to −130 dBc/Hz.

19. The optical system of claim 16, wherein the active section comprises a distributed feedback (DFB) grating and the isolator-free laser comprises a distributed reflector (DR) laser, a DFB laser with weak optical feedback (DFB+R laser), or a DR laser with weak optical feedback (DR+R laser).

20. The optical system of claim 13, wherein:
the etalon or the DBR mirror comprises the DBR mirror;
the DBR mirror comprises a first DBR section with a first kappa and a second DBR section with a second kappa less than the first kappa;
the first DBR section is positioned between the active section and the second DBR section; and
the isolator-free laser comprises a two-kappa DBR laser.
